(19) United States
(12) Patent Application Publication
(10) Pub. No.: US 2003/0218507 A1
(43) Pub. Date: Nov. 27, 2003

(54) Amplification device

(75) Inventors: Akira Inoue, Hyogo (JP); Akira Ohta, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/247,433

(22) Filed: Sep. 20, 2002

(30) Foreign Application Priority Data
May 21, 2002 (JP) 2002-146682

(51) Int. Cl. H03F 1/52

(52) U.S. Cl. 330/298

(57) ABSTRACT

A signal corresponding to a progressive wave's power is extracted from a progressive-wave coupler connected between an output of an amplifier and an antenna. A signal corresponding to reflected power is also extracted from a coupler for reflection. An arithmetic circuit calculates a voltage supplied to the amplifier and a control voltage is supplied to the amplifier, and furthermore a power supply voltage based on the result of the operation is supplied from a DC-DC converter to the amplifier.

### DESCRIPTION OF THE PRIOR ART

1. Field of the Invention

The present invention relates generally to amplification devices and particularly to those used in mobile phones to amplify a signal of a high frequency such as a microwave.

2. Conventional Art

FIG. 15 is a circuit diagram showing a power amplification device used in a conventional mobile phone. In the figure an amplifier 1 is formed of a semiconductor device of a GaAsFET, a HBT or the like and it has an output terminal connected to an input of an isolator 2 and an input terminal connected to a microwave input terminal 3. Isolator 2 has an output connected to an antenna 4. Amplifier 1 has a voltage supply terminal 5 receiving a power supply voltage Vdd and a control voltage terminal 6 receiving a control voltage Vgg. In response to control voltage Vgg a value of a current flowing through amplifier 1 is set.

When a radio frequency (RF) signal of power Pi is applied to microwave input terminal 3, the RF signal is amplified by amplifier 1 and an electric wave is radiated from antenna 4 through isolator 2 into the air for communication. In general, power supply voltage Vdd is supplied from a battery and thus has a substantially constant voltage.

For a mobile phone or the like, antenna 4 may be adjacent to a wall, a conductor or the like. This would introduce an offset from a designed value of 50 Ω in impedance and power radiated by antenna 4 and transmitted can thus return to amplifier 1. If the reflection of the wave returns to amplifier 1, the amplifier's output impedance would be offset from the desired value of 50 Ω significantly. A specification for distortion such as adjacent channel power leakage (ACP) would in general no longer be satisfied and an electric wave is thus disadvantageously output in a band other than a communication channel. To prevent this, isolator 2 is inserted between amplifier 1 and antenna 4.

However, isolator 2 is attached on as large an area as 5×5 mm², which is an obstacle to miniaturization. Furthermore, isolator 2 is formed of a magnet. It is as high as 1.7 to 1.5 mm, which is also an obstacle to reduction in thickness. Furthermore, isolator 2 introduces a loss of approximately 0.68 dB, which impairs efficiency, and the provision of isolator 2 also requires an accordingly increased cost.

### SUMMARY OF THE INVENTION

Therefore a main object of the present invention is to provide an amplification device dispensing with an isolator and still capable of amplifying a signal of a high frequency such as a microwave without impaired distortion characteristics despite a reflection of a wave introduced at an antenna.

The present invention generally provides an amplification device amplifying a signal of a high frequency wave flowing through an antenna, including: an amplifier amplifying an input wave signal to derive an output wave signal at the antenna; a reflected-wave detection circuit provided closer to an output of the amplifier to detect an amount of a wave reflected from the antenna; and a control circuit driven by an output of the reflected-wave detection circuit to control a voltage supplied to the amplifier to change a state of an operation of the amplifier.

Preferably the amplification device further includes a supply current detection circuit detecting a current supplied to the amplifier and when the supply current detection circuit provides an output indicating that a large current is detected the control circuit operates to reduce the power supply voltage supplied to the amplifier.

More preferably the amplification device further includes an input wave detection circuit detecting an amount of a wave input to the amplifier and the control circuit is driven by outputs respectively of the reflected-wave detection circuit and the input wave detection circuit to change the power supply voltage supplied to the amplifier.

Still more preferably the amplification device further includes a variable gain amplifier connected to precede the amplifier and externally provided with a gain setting value and the control circuit is driven by the gain setting value of the variable gain amplifier to change the power supply voltage supplied to the amplifier.

Still more preferably the amplification device further includes an output wave detection circuit detecting an amount of a wave output from the amplifier and the control circuit is driven by outputs respectively of the reflected-wave detection circuit and the output wave detection circuit to change the power supply voltage supplied to the amplifier.

Still more preferably the amplification device further includes a filter circuit connected between an output of the amplifier and the reflected-wave detection circuit and having a variable capacitor and the control circuit is driven by the output of the reflected-wave detection circuit to change a capacitance of the variable capacitor to change an output impedance of the amplifier.

Still more preferably the control circuit includes a memory table previously storing a control value and it is driven by the output of the reflected-wave detection circuit to read a corresponding control value from the memory table to output a control signal for controlling the power supply voltage.

Thus in accordance with the present invention an isolator can be dispensed with and a signal of a high frequency such as a microwave can still be amplified without impaired distortion characteristics despite a reflection of a wave introduced at an antenna. The area for the isolator is no longer required and miniaturization can thus be achieved. A magnet for the isolator can thus also be dispensed with and a height accordingly reduced can contribute to a reduced thickness. Furthermore the cost for the isolator can be saved to contribute to reduced cost and the loss introduced by the isolator can also be eliminated to provide the amplifier with enhanced efficiency.

The foregoing and other objects, features, aspects and advantages of the present invention will become more apparent from the following detailed description of the present invention when taken in conjunction with the accompanying drawings.

### BRIEF DESCRIPTION OF THE DRAWINGS

In the drawings:

FIG. 1 is a block diagram showing an amplification device of the present invention in a first embodiment;

FIG. 2 shows one example of a circuit diagram specifically showing the FIG. 1 amplifier;

FIG. 3 shows an example of a directional coupler;

FIG. 4 represents output power versus input power characteristics of the FIG. 1 amplifier;

FIG. 5 represents load pull characteristics of a final-stage transistor in an amplifier for Vdd=3.4V;

FIG. 6 represents load pull characteristics of the final-stage transistor in the amplifier for Vdd=4.0V;

FIG. 7 represents power supply voltage Vdd set by using voltage Va proportional to output power Pout and voltage Vb proportional to reflected power;

FIG. 8 represents exemplary load pull of a final-stage transistor obtained when the FIG. 7 relationship is used to vary power supply voltage Vdd;

FIG. 9 is a block diagram showing the amplification device of the present invention in a second embodiment;

FIG. 10 represents load pull characteristics of a final-stage transistor of an amplifier of the FIG. 9 embodiment;

FIGS. 11-13 are block diagrams showing the amplification device of the present invention in third to fifth embodiments, respectively;

FIG. 14 shows an arithmetic circuit in a sixth embodiment of the present invention; and

FIG. 15 is a circuit diagram showing a power amplifier used in a conventional mobile phone.

### DESCRIPTION OF THE PREFERRED EMBODIMENTS

First Embodiment

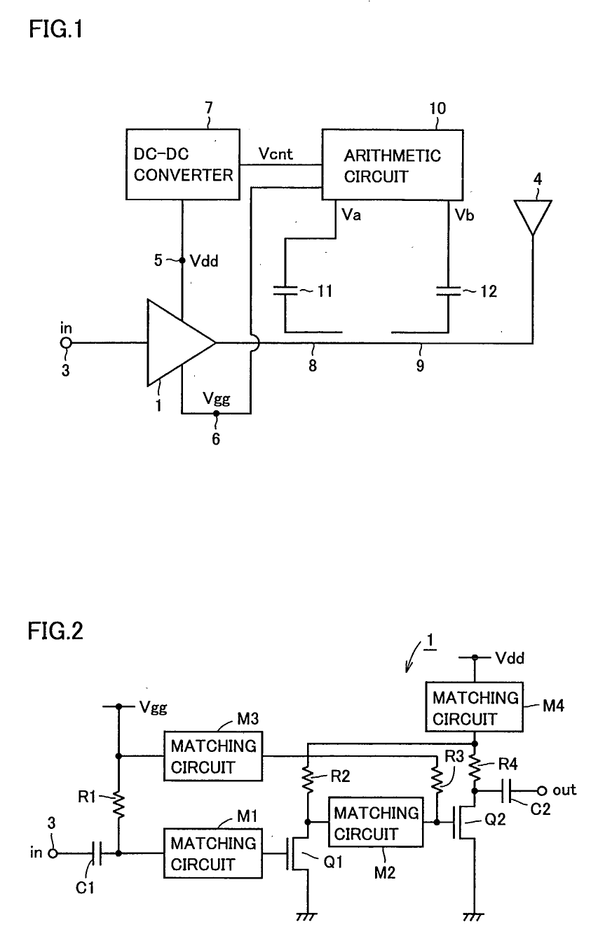

FIG. 1 is a circuit diagram showing an amplification device of the present invention in a first embodiment. As shown in the figure, an amplifier 1 has an input terminal connected to a microwave input terminal 3 and an output connected to an antenna 4 via a progressive wave (PW) coupler 8 serving as a circuit detecting an amount of a wave output and a reflected wave (RW) coupler 9 serving as a circuit detecting an amount of a wave reflected. It does not use an isolator as conventional. Amplifier 1 has voltage supply terminal 5 receiving a power supply voltage Vdd from a DC-DC converter 7 serving as a power supply converter, and a control voltage terminal 6 receiving a control voltage Vgg. Depending on control voltage Vgg the value of a current flowing through amplifier 1 is set.

PW coupler 8 extracts a signal corresponding to a progressive wave's power. Voltage Va corresponding to this signal is extracted by a capacitor 11 and provided to an arithmetic circuit 10. RW coupler 9 extracts a signal corresponding to power of a wave reflected by antenna 4 and a capacitor 12 extracts a voltage Vb which is in turn provided to arithmetic circuit 10. Arithmetic circuit 10 is formed for example by a Si-MOSFET or a bipolar transistor and it generates a voltage Vcnt corresponding to voltages Va and Vb provided from capacitors 11 and 12. Voltage Vcnt is equal to fn (Va, Vb). Arithmetic circuit 10 supplies Voltage Vcnt to DC-DC converter 7. In response to voltage Vcnt, DC-DC converter 7 generates power supply voltage Vdd.

FIG. 2 shows an example of a circuit diagram specifically showing the FIG. 1 amplifier 1. In the figure, microwave input terminal 3 receives a microwave input signal which is in turn passed through a capacitor C1 and a matching circuit M1 and received by a FET Q1 at the gate. A point connecting capacitor C1 and matching circuit M1 receives control voltage Vgg through a resistor R1. FET Q1 has its drain connected to the gate of a FET Q2 through a matching circuit M2 and also receiving power supply voltage Vdd through a matching circuit M4 and a resistor R2. FET Q1 has its source grounded and FET Q2 has its gate receiving control voltage Vgg through a matching circuit M3 and a resistor R3.

FET Q2 has its drain connected to an output terminal via a capacitor C2 and also receiving power supply voltage Vdd through a matching circuit M4 and a resistor R4. FET Q2 has its source grounded. Matching circuits M1-M4 are configured for example by a combination of an inductor, a capacitor and a resistor. Amplifier 1 thus configured amplifies an input wave signal input to microwave input terminal 3, with a prescribed amplification rate of FETs Q1 and Q2, and outputs the signal at the output terminal.

Note that while the FIG. 2 amplifier is formed by a FET, it may be formed by a bipolar transistor. For the FIG. 2 amplifier 1 FETs Q1 and Q2 have their drains receiving power supply voltage Vdd and their gates receiving control voltage Vgg, whereas for an amplifier formed by a bipolar transistor the corrector receives power supply voltage Vdd and the base receives control voltage Vgg.

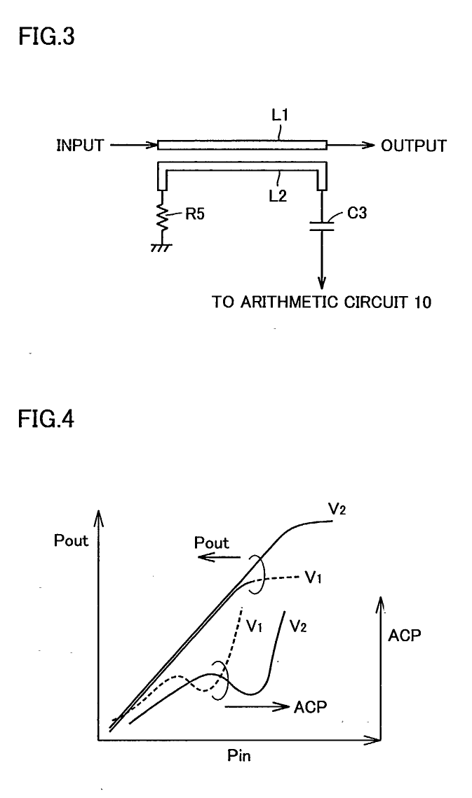

FIG. 3 shows one example of a directional coupler forming PW coupler 8 shown in FIG. 1. On a substrate there are arranged conductive patterns L1 and L2 in parallel, each in a strip. Conductive pattern L1 has one end receiving an input signal and the other end outputting the signal. Conductive pattern L2 has one end bent by a right angle and having a tip grounded with a resistor R5 posed therebetween, and the other end also bent by a right angle and having a tip connected to a capacitor C3 through which a signal corresponding to a progressive wave's power is extracted.

When a signal output from amplifier 1 is input to one end of conductive pattern L1 and extracted from the other end of the pattern, conductive pattern L2 has induced therein a power corresponding to the progressive wave and through capacitor C3 a signal corresponding to the progressive wave's power is extracted. When a wave reflected from antenna 4 is input to the other end of conductive pattern L1 and conductive pattern L2 has the reflected wave's power induced therein a component of the signal flows to ground through resistor R5 and a progressive-wave component based on a progressive wave's power can thus be extracted.

Note that RW coupler 9 may be similar in configuration to the FIG. 3 directional coupler. More specifically, RW coupler 9 is configured with the FIG. 3 resistor R5 and capacitor C3 connected in reverse to extract a signal corresponding to a reflected wave's power.

FIG. 4 represents output power versus input power characteristics of the FIG. 1 amplifier. In general, amplifier 1 has characteristics, as shown in FIG. 4, that the higher power supply voltage Vdd is, the more an output power extends. More specifically, for power supply voltage Vdd set to be a high voltage V1 and that set to be a low voltage V2, the dependence of output power Pout and distortion (ACP) on input power Pin is such that Pout extends more for high voltage V2 than low voltage V1 and so does input power Pin with distortion (ACP) degrading. Thus for a single output power Pout high voltage V2 tends to be able to reduce ACP more than low voltage V1.

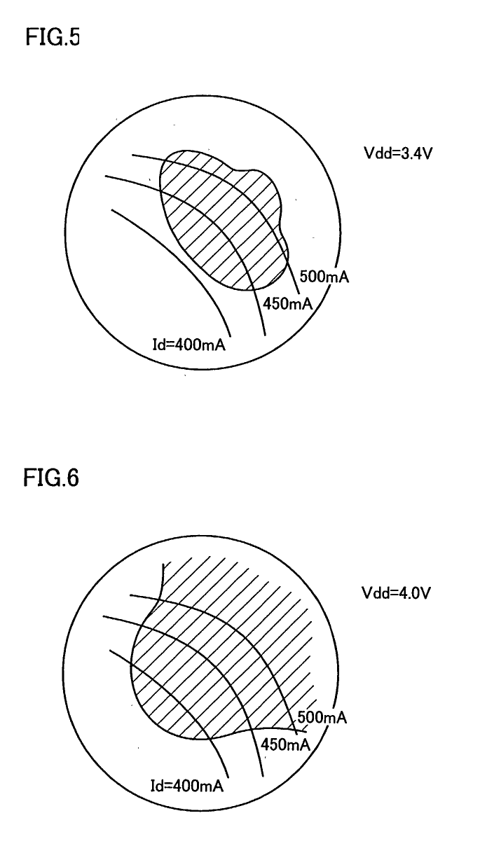

FIGS. 5 and 6 represent load pull characteristics of a final-stage transistor of an amplifier for a Vdd of 3.4V and a Vdd of 4.0V, respectively. The load pull characteristics represent how characteristics vary for an impedance of an output's side, indicating a current Id and distortion for each impedance of a transistor's output's side for a frequency f of 1 GHz, output power Pout of 1W and control voltage Vgg having a constant value.

Note that the impedance is represented in a Smith chart with a center Z0 standardized by the transistor's output impedance of 6 Ω. In FIGS. 5 and 6 a hatched portion represents a region in which distortion (ACP) is no more than the standardized value.

Current Id is substantially the same regardless of power supply voltage Vdd, having a tendency to increase from lower left to upper right. That is, it can be understood that the larger current Id is, the smaller distortion is. In FIG. 5 a center's distortion is satisfactory, whereas in FIG. 6 distortion improves over a wide range, although due to higher voltage Vdd larger power is consumed. If power supply voltage Vdd is increased to satisfy distortion without an isolator, the Smith chart's center is associated with increased power consumption, resulting in decreased efficiency.

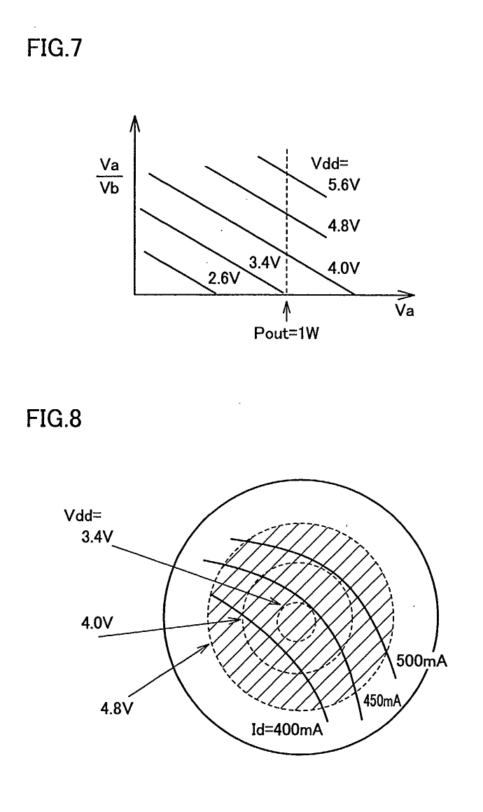

Accordingly in the present embodiment a voltage Va proportional to output power Pout and a voltage Vb proportional to reflected power, as shown in FIG. 7, are used to set power supply voltage Vdd. In FIG. 7, the horizontal axis represents voltage Va proportional to output power Pout and the horizontal axis represents a ratio of voltage Va proportional to output power Pout to voltage Vb proportional to reflected power, indicating a value obtained as a result of an experiment. It can be seen from the FIG. 7 that for larger reflected power, power supply voltage Vdd needs to be set higher. Note that the dotted line indicates a line of voltage Va for output power Pout of 1W.

Using the relationship between voltage Va proportional to output power Pout and voltage Vb proportional to reflected power, as shown in FIG. 7, to set power supply voltage Vdd allows the smith chart's center, free of reflection, to be associated with reduced power consumption with a low power supply voltage Vdd (of 3.4V), while power supply voltage Vdd is increased in response to reflection's magnitude (Vb/Va) to satisfy distortion.

FIG. 8 exemplarily represents load pull of a final-stage transistor that is provided when the FIG. 7 relationship is used to vary power supply voltage Vdd. In FIG. 8, the center is associated with power supply voltage Vdd of 3.4V, although power supply voltage Vdd is set to increase as a reflection coefficient P, or Vb/Va, increases. Thus in FIG. 8 distortion (ACP) satisfies a specification in the entirety of a region internal to power supply voltage Vdd of 4.8V, which is shown hatched. By setting Vcnt by the FIG. 1 arithmetic circuit in the FIG. 7 relationship, the amplifier 1 power supply voltage Vdd can be changed by DC-DC converter 7, and the amplifier 1 transistor can thus have an output with load pull characteristics provided to satisfy distortion over a wide range, as shown in FIG. 8.

Thus an isolator can be dispensed with and amplifier 1 can still be configured to satisfy ACP if antenna 4 introduces reflection. Furthermore, when antenna 4 does not introduce reflection, power supply voltage Vdd is low and power consumption in normal use would thus not be increased. Now that the isolator can be removed, an area therefor is no longer required. Miniaturization can thus be achieved. Furthermore, a magnet serving as a component of the isolator can also be eliminated, which contributes to a reduced height and hence a reduced thickness. Furthermore, the cost for the isolator is no longer required and a cost reduction can thus be achieved. Furthermore, the loss introduced by the isolator can be eliminated to contribute to enhanced efficiency of amplifier 1.

Note that while in the present embodiment power supply voltage Vdd is set in the FIG. 7 relationship by linear approximation, Vdd may be changed by a different function such as a curve more approximate to that as provided in effect.

Furthermore, changing not only Vcnt but also the amplifier 1 control voltage Vgg in accordance to Va, Vb/Va allows the amplifier's distortion and efficiency characteristics to be controlled more precisely to provide amplifier 1 with further enhanced efficiency.

Second Embodiment

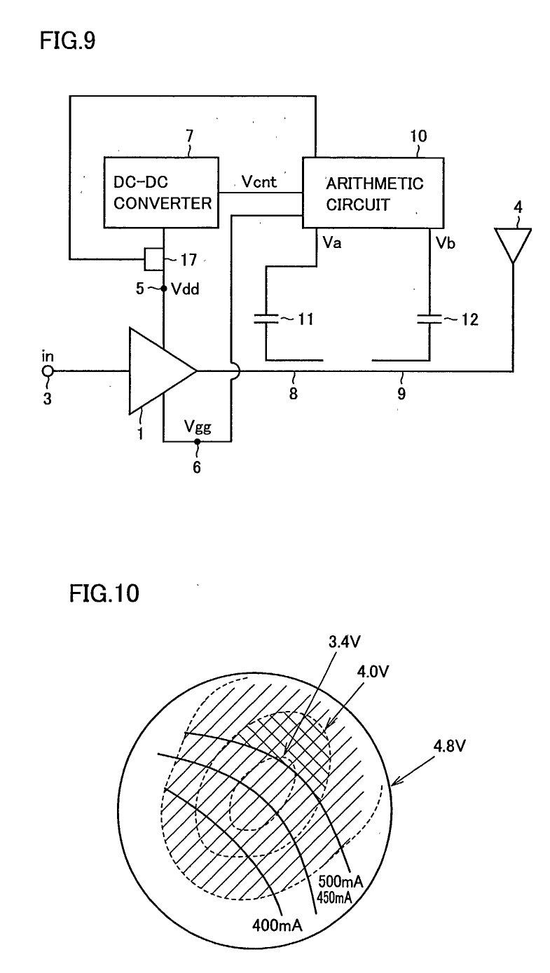

FIG. 9 shows the amplification device of the present invention in a second embodiment. In the figure the present embodiment is identical in configuration to FIG. 1 except that amplifier 1 receives a supply current Id monitored by an Id monitor circuit 17 and the monitor provides an output to arithmetic circuit 10. Arithmetic circuit 10 generates voltage Vcnt or a current depending on the output of Id monitor circuit 17 monitoring supply current Id.

FIG. 10 represents load pull characteristics of a final-stage transistor of the amplifier of the embodiment shown in FIG. 9. In the present embodiment Id monitor circuit 17 can monitor supply current Id and arithmetic circuit 10 can perform an operation to allow a region with larger supply current Id to be associated with lower power supply voltage Vdd so as to set power supply voltage Vdd to be low over a wider range.

As has been shown in FIGS. 5 and 6, in general, distortion tends to be smaller for larger supply current Id. As such, distortion can be satisfied if power supply voltage Vdd is reduced in a region associated with large supply current Id, as shown in FIG. 10. This can effectively reduce power consumption in the region with large supply current Id. Thus, even if an antenna's impedance varies, an operation with low power consumption can be achieved over a wider impedance range.

As can be understood when FIG. 10 is compared with FIG. 8, in FIG. 8 a hatched range satisfying a specification extends concentrically as power supply voltage Vdd increases, whereas in FIG. 10 it extends in the form of an ellipse extending in an upper right direction. It can be understood that for example for power supply voltage Vdd of 4 V a cross hatched portion of FIG. 10 is improved as compared to that of FIG. 8.

Third Embodiment

FIG. 11 shows an amplification device of the present invention in a third embodiment. In the present embodiment the FIG. 1 PW coupler is dispensed with and from an input wave signal of amplifier 1 via a capacitor 15 a voltage V_{T} monitored is provided to arithmetic circuit 10 and furthermore via RW coupler 9 capacitor 12 extracts a signal corresponding to power effected at antenna 4 and provides voltage Vb to arithmetic circuit 10. Arithmetic circuit 10 uses voltage V_{T} and voltage Vb to perform an operation to calculate power supply voltage Vdd and set it for amplifier 1. This case is associated with a small reverse gain and thus Va∝V_{T}. A PW coupler can thus be dispensed with to perform an operation similar to that of the FIG. 1 amplification device.

Furthermore in the present embodiment a single coupler can be eliminated to contribute to a reduced area and the loss corresponding to the single coupler can also be eliminated to provide amplifier 1 with increased efficiency.

Fourth Embodiment

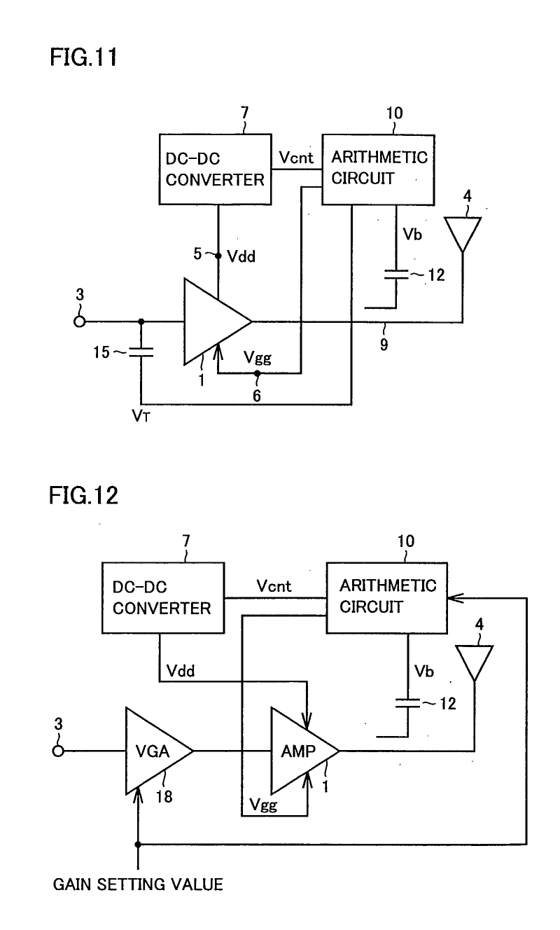

FIG. 12 shows the amplification device of the present embodiment in a fourth embodiment.

In the FIG. 11 embodiment an input power is monitored on an input's side of amplifier (AMP) 1, whereas in the FIG. 12 embodiment a variable gain amplifier (VGA) 18 receives a gain setting value to allow calculation of a power output from variable gain amplifier 18. Using the value to calculate a value of an input of amplifier 1 eliminates the necessity of monitoring input power. The present embodiment thus configured can be as effective as the third embodiment.

Fifth Embodiment

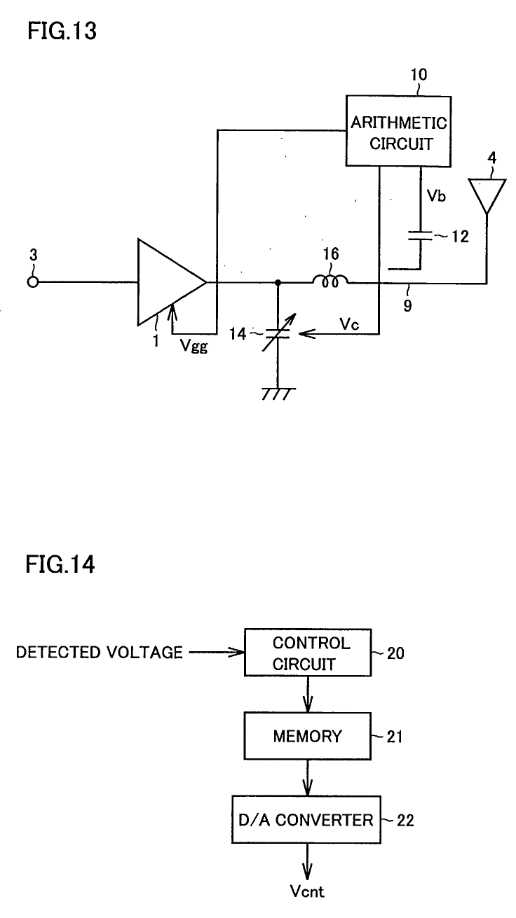

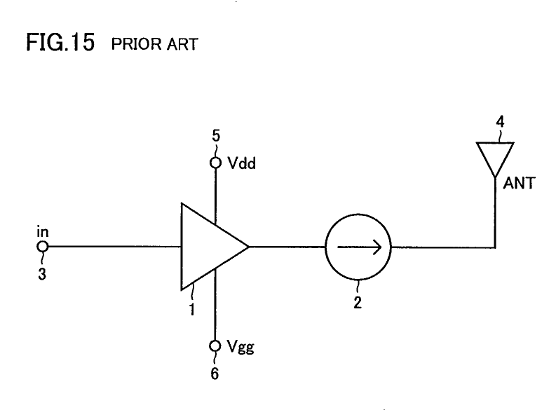

FIG. 13 shows the amplification device of the present invention in a fifth embodiment. In the present embodiment, a variable capacitor 14 is connected between an output of amplifier 1 and ground and an inductor 16 is connected between an output of amplifier 1 and RW coupler 9 in series to form a lowpass filter. Variable capacitor 14 can be formed for example of a FET or a diode. Variable capacitor 14 receives a voltage Vc from arithmetic circuit 10 to set a value in capacitance for example by an LSI. Note that inductor 16 of the lowpass filter that is provided subsequent to the variable capacitor in this example may precede the capacitor.

Furthermore the present embodiment is different from the first to fourth embodiments in that power supply voltage Vdd is not controlled and DC-DC converter 7 is accordingly not provided, and the amplifier 1 output impedance is controlled. More specifically in the present embodiment arithmetic circuit 10 outputs capacitance setting voltage Vc and in response to voltage Vc variable capacitor 14 varies in capacitance to allow amplifier 1 to vary in output impedance. Arithmetic circuit 10 monitors and detects an amount of a wave reflected from RW coupler 9 and in response to the detection when an amount of reflection is increased to fail to satisfy ACP it controls capacitance setting voltage Vc to allow the amplifier 1 output impedance to vary toward satisfactory ACP.

The present embodiment can dispense with DC-DC converter 7 and accordingly save the cost for the converter as well as provide an accordingly reduced size.

Furthermore in the present embodiment control voltage Vgg as well as capacitance setting voltage Vcc may additionally be controlled. Power supply voltage Vdd may of course be controlled, as described previously, additionally.

Sixth Embodiment

In each of the above embodiments arithmetic circuit 10 is formed for example of an operational amplifier, it may be configured as shown in FIG. 14. More specifically, a memory 21 may store a control voltage value in the form of a table. Each detected voltage may be provided to a control circuit 20. Control circuit 20 may read a corresponding control voltage value from memory 21. A D/A converter 22 may convert the value to an analog value. Control signal Vcnt may be provided to DC-DC converter 7.

In the present embodiment a control value in the table stored in memory 21 can be used to provide more precise voltage control.

Thus in the embodiments of the present invention an amount of a wave reflected from an antenna is detected and referred to to control a voltage supplied to an amplifier to change a state of an operation of the amplifier so that an isolator can be dispensed with and a signal of a high frequency such as a microwave can still be amplified without impaired distortion characteristics despite a reflected wave introduced at an antenna.

Accordingly the area for the isolator is no longer required and miniaturization can thus be achieved. Furthermore, a magnet can be eliminated, which contributes to a reduced height and hence a reduced thickness. Furthermore, the cost for the isolator is no longer required and a cost reduction can thus be achieved. Furthermore, the loss introduced by the isolator can be eliminated to contribute to enhanced efficiency of the amplifier.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An amplification device amplifying a signal of a high frequency wave flowing through an antenna, comprising:
an amplifier amplifying an input wave signal to derive an output wave signal at said antenna;
a reflected-wave detection circuit provided closer to an output of said amplifier to detect an amount of a wave reflected from said antenna; and
a control circuit driven by an output of said reflected-wave detection circuit to control a voltage supplied to said amplifier to change a state of an operation of said amplifier.

2. The amplification device of claim 1, wherein as said output from said reflected-wave detection circuit increases, said control circuit operates to increase a power supply voltage supplied to said amplifier.

3. The amplification device of claim 1, wherein said reflected-wave detection circuit is a directional coupler connected between an output of said amplifier and said antenna.

4. The amplification device of claim 1, further comprising a supply current detection circuit detecting a current supplied to said amplifier, wherein when said supply current detection circuit provides an output indicating that a large current is detected said control circuit operates to reduce a power supply voltage supplied to said amplifier.

5. The amplification device of claim 1, comprising an input wave detection circuit detecting an amount of a wave input to said amplifier, wherein said control circuit is driven by outputs respectively of said reflected-wave detection circuit and said input wave detection circuit to change said power supply voltage supplied to said amplifier.

6. The amplification device of claim 1, further comprising a variable gain amplifier connected to precede said amplifier and externally provided with a gain setting value, wherein said control circuit is driven by said gain setting value of said variable gain amplifier to change said power supply voltage supplied to said amplifier.

7. The amplification device of claim 1, further comprising an output wave detection circuit detecting an amount of a wave output from said amplifier, wherein said control circuit is driven by outputs respectively of said reflected-wave detection circuit and said output wave detection circuit to change said power supply voltage supplied to said amplifier.

8. The amplification device of claim 7, wherein said output wave detection circuit is a directional coupler connected between an output of said amplifier and said antenna.

9. The amplification device of claim 1, comprising a filter circuit connected between an output of said amplifier and said reflected-wave detection circuit and having a variable capacitor, wherein said control circuit is driven by said output of said reflected-wave detection circuit to change a capacitance of said variable capacitor to change an output impedance of said amplifier.

10. The amplification device of claim 1, wherein said control circuit controls a control voltage for setting a current flowing through said amplifier.

11. The amplification device of claim 1, wherein said control circuit includes a memory table previously storing a control value and driven by said output of said reflected-wave detection circuit to read a corresponding control value from said memory table to output a control signal for controlling said power supply voltage.
